(19) United States
(12) Patent Application Publication
(10) Pub. No.: US 2021/0367064 A1
(43) Pub. Date: Nov. 25, 2021

(54) LDMOS DEVICE AND METHOD FOR MAKING THE SAME

(71) Applicant: Hua Hong Semiconductor (Wuxi) Limited, Wuxi (CN)

(72) Inventors: Junwen LIU, Wuxi (CN); Hualun CHEN, Wuxi (CN)

(73) Assignee: Hua Hong Semiconductor (Wuxi) Limited, Wuxi (CN)

(21) Appl. No.: 17/092,547

(22) Filed: Nov. 9, 2020

(30) Foreign Application Priority Data
May 25, 2020 (CN) 202010453206.5

(51) Int. Cl. H01L 29/66; H01L 29/78; H01L 29/06; H01L 29/10; H01L 29/08; H01L 21/762

(52) U.S. Cl. CPC H01L 29/66681; H01L 29/7816; H01L 21/762; H01L 29/1095; H01L 29/0873; H01L 29/0653

(57) ABSTRACT

A method for manufacturing an LDMOS device includes: forming STI in a substrate; forming a well region in the substrate; forming a body region at one end of the well region, and forming a drift region at the other end of the well region; forming a gate dielectric layer on the substrate; forming a gate structure; forming a drain region in the drift region, and forming a source region in the body region; forming a salicide block layer, wherein the salicide block layer is composed of stacked dielectric layer and conductive layer, the salicide block layer covers the drift region between the gate structure and the drain region, and the salicide block layer extends above the gate structure; forming salicides on the tops of the drain region, the source region, and the gate structure; depositing an interlayer dielectric layer; and forming contacts in the interlayer dielectric layer.

### CROSS-REFERENCES TO RELATED APPLICATIONS

This application claims the priority to Chinese patent application No. 202010453206.5 filed at CNIPA on May 25, 2020, and entitled “LDMOS DEVICE AND METHOD FOR MAKING THE SAME”, the disclosure of which is incorporated herein by reference in entirety.

### TECHNICAL FIELD

The present application relates to the field of semiconductor manufacturing, in particular to manufacturing technology of LDMOS devices.

### BACKGROUND

The lateral diffused MOSFET (LDMOS) device is a common power device, and the breakdown voltage and on-resistance are important parameters for measuring the performance thereof.

The LDMOS device pursues high breakdown voltage and low on-resistance. The breakdown voltage refers to the maximum voltage that can be applied between the drain and gate of the LDMOS device in the case of no breakdown. The breakdown voltage and on-resistance of the traditional LDMOS device is limited by each other. An increase in the breakdown voltage leads to an increase in the on-resistance, and a decrease in the on-resistance leads to a decrease in the breakdown voltage. Thus, a balance point needs to be found between the on-resistance and the breakdown voltage. Currently, a gate field plate or a metal field plate can be used to increase the breakdown voltage to a certain extent.

### BRIEF SUMMARY

According to some embodiments in this application, a method for manufacturing an LDMOS device is disclosed in the following steps: forming shallow trench isolation in a substrate, wherein the shallow trench isolation is used to define active regions/forming a well region in the substrate; forming a body region at one end of the well region, and forming a drift region at the other end of the well region; forming a gate dielectric layer on the surface of the substrate; forming a gate structure of the LDMOS device, wherein the gate structure covers a portion of the drift region and a portion of the body region by crossing from one to the other; forming a drain region of the LDMOS device in the drift region, and forming a source region of the LDMOS device in the body region; forming a salicide block layer, wherein the salicide block layer is composed of stacked dielectric layer and conductive layer, the salicide block layer covers the drift region between the gate structure and the drain region, and the salicide block layer extends above the gate structure; forming salicides on the tops of the drain region, the source region, and the gate structure; depositing an interlayer dielectric layer; and forming contacts in the interlayer dielectric layer, wherein the contacts correspond to the drain region, the source region, the gate structure, and the salicide block layer.

The LDMOS device is manufactured in an integrated process with manufacturing the active CMOS devices.

### BRIEF DESCRIPTION OF THE DRAWINGS

FIG. 1 shows the device cross sectional view of an LDMOS device, according to one embodiment of the present application.

FIG. 2 is a flowchart of the method for manufacturing an LDMOS device, according to one embodiment of the present application.

FIG. 3 is a flowchart of a method for manufacturing an LDMOS device, according to another embodiment of the present application.

FIG. 4 shows the device cross sectional view of the CMOS and LDMOS device, according to another embodiment of the present application.

### DETAILED DESCRIPTION OF THE DISCLOSURE

The technical solutions in this application will be clearly and completely described below with reference to the drawings. Obviously, the described embodiments are part of the embodiments of the application, instead of all them. Based on the embodiments in the present application, all other embodiments obtained by one skilled in the art without contributing any inventive labor shall fall into the protection scope of the present application.

In the description of this application, it should be noted that the orientation or positional relationship indicated by the terms “center”, “upper”, “lower”, “left”, “right”, “vertical”, “horizontal”, “inside”, “outside”, or the like is based on the orientation or positional relationship shown in the drawings, is only for the convenience of describing this application and simplified description, and does not indicate or imply that the indicated device or element must have a specific orientation or be configured and operated in a specific orientation. Therefore, the orientation or positional relationship should not to be construed as limitations on the present application. In addition, the terms “first,” “second,” and “third” are used for descriptive purposes only, and should not be construed to indicate or imply relative importance.

In the description of this application, it should be noted that the terms “installation”, “connected”, and “connection” should be understood in a broad sense, unless explicitly stated and defined otherwise, for example, they may be fixed connection or removable connection, or integral connection; can be mechanical or electrical connection; can be direct connection, or indirect connection through an intermediate medium, or the internal communication of two elements, and can be wireless or wired connection. For those of ordinary skill in the art, the specific meanings of the above terms in this application can be understood in specific situations.

In addition, the technical features involved in the different implementations of the present application described below can be combined with each other as long as they do not conflict with each other.

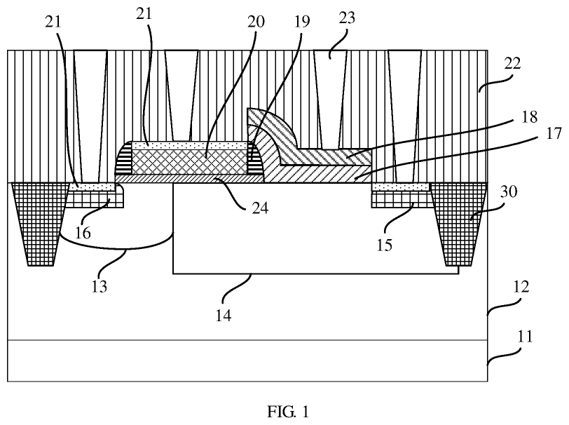

FIG. 1 illustrates the device cross sectional view of an LDMOS device, according to one embodiment of the present disclosure.

The LDMOS device includes at least a substrate 11, a well region 12 in the substrate, a body region 13, a drift region 14, a gate structure, and a salicide block layer.

The salicide block layer is used to prevent formation of salicides at a silicon interface between a gate and a drain.

The body region 13 and the drift region 14 are in the well region 12, a drain region 15 is at one end of the drift region 14, and a source region 16 is at one end of the body region 14.

The gate structure covers a portion of the drift region 14 and a portion of the body region 13 by crossing from one to the other.

Referring to FIG. 1, a gate dielectric layer 24 is between the gate structure and the substrate. In some examples, the gate dielectric layer 24 is a silicon dioxide layer.

The salicide block layer is composed of stacked a dielectric layer 17 and a conductive layer 18, the dielectric layer 17 is located on the substrate, and the conductive layer 18 is located on the dielectric layer 17.

The salicide block layer covers the drift region between the gate structure and the drain region 15, and the salicide block layer extends above the gate structure.

Referring to FIG. 1, the salicide block layer covers a gate sidewall 19.

Salicides 21 are separately formed on the tops of the drain region 15, the source region 16, and the gate structure.

The drain region 15, the source region 16, the gate structure, and the salicide block layer are respectively led out from contacts 23 in an interlayer dielectric layer 22.

In summary, by stacking a dielectric layer and a conductive layer to form the silicide block layer, the salicide block layer is used as a field plate, the breakdown voltage and reliability of the LDMOS device have been further improved.

Referring to FIG. 1, the gate structure includes a polysilicon gate 20 and the gate sidewalls 19, and the salicide 21 is formed on the top of the polysilicon gate 20.

In some examples, the conductive layer in the salicide block layer is a metal layer.

In some examples, the conductive layer in the salicide block layer consists a polysilicon layer and a salicide layer on the polysilicon layer; and the salicide layer on the polysilicon layer is formed during formation of the salicides on the tops of the drain region, the source region, and the polysilicon gate.

In some examples, the polysilicon layer in the salicide block layer is formed by doped polysilicon.

In some examples, a CMOS device is formed on the substrate; and shallow trench isolation 30 is formed in the substrate, wherein the shallow trench isolation 30 is used to define active regions, referring to FIG. 1.

In some examples, the LDMOS device is a P-type device, or the LDMOS device is an N-type device.

If the LDMOS device is an N-type device, the well region is P-type, the drift region is N-type, the body region is P-type, and doping types of the source region and the drain region are N-type; and if the LDMOS device is a P-type device, the well region is N-type, the drift region is P-type, the body region is N-type, and doping types of the source region and the drain region are P-type.

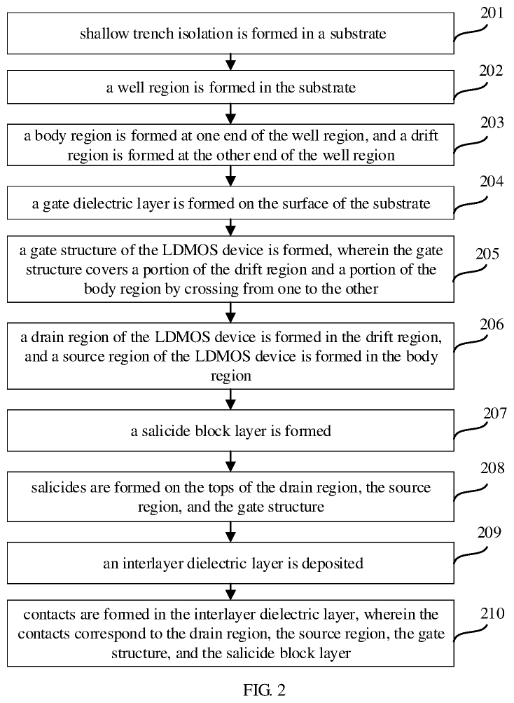

FIG. 2 is a flowchart of a method for manufacturing an LDMOS device, according to another embodiment of the present disclosure.

In step 201, shallow trench isolation is formed in a substrate.

The shallow trench isolation defines active device regions for LDMOS devices and/or CMOS devices.

In step 202, a well region is formed in the substrate.

The well region is formed in the active region on the substrate via an ion implantation process.

In step 203, a body region is formed at one end of the well region, and a drift region is formed at the other end of the well region.

The body region is formed at one end of the well region and the drift region is formed at the other end of the well region respectively by performing an ion implantation process.

In step 204, a gate dielectric layer is formed on the surface of the substrate.

In some examples, the gate dielectric layer is formed on the surface of the substrate by performing a thermal oxidation process, and the gate dielectric layer is a silicon dioxide layer.

In step 205, a gate structure of the LDMOS device is formed, wherein the gate structure covers a portion of the drift region and a portion of the body region by crossing from one to the other.

The gate structure of the LDMOS device is formed on the gate dielectric layer, and the gate structure covers a portion of the drift region and a portion of the body region by crossing from one to the other.

In step 206, a drain region of the LDMOS device is formed in the drift region, and a source region of the LDMOS device is formed in the body region.

In some examples, ions are implanted into two sides of the gate structure via a self-alignment process and an annealing process, to form the drain region of the LDMOS device in the drift region and form the source region of the LDMOS device in the body region.

In step 207, a salicide block layer is formed.

The salicide block layer is formed by stacking a dielectric layer and a conductive layer, the salicide block layer covers the drift region between the gate structure and the drain region, and the salicide block layer extends above the gate structure.

In the salicide block layer, the dielectric layer is not conductive, and the dielectric layer is located below the conductive layer.

The salicide block layer is used to prevent formation of salicides on the surface of the drift region between the gate structure and the drain region.

In step 208, salicides are formed on the tops of the drain region, the source region, and the gate structure.

The salicides are formed on the top of the drain region, the top of the source region, and the top of the gate structure at the same time.

In step 209, an interlayer dielectric layer is deposited.

The interlayer dielectric layer is deposited on the substrate, and perform a chemical-mechanical planarization process.

In step 210, contacts are formed in the interlayer dielectric layer, wherein the contacts correspond to the drain region, the source region, the gate structure, and the salicide block layer.

The contacts are formed in the interlayer dielectric layer via photolithography and etching processes, and the drain region, the source region, the gate structure, and the salicide block layer are led out from the contacts.

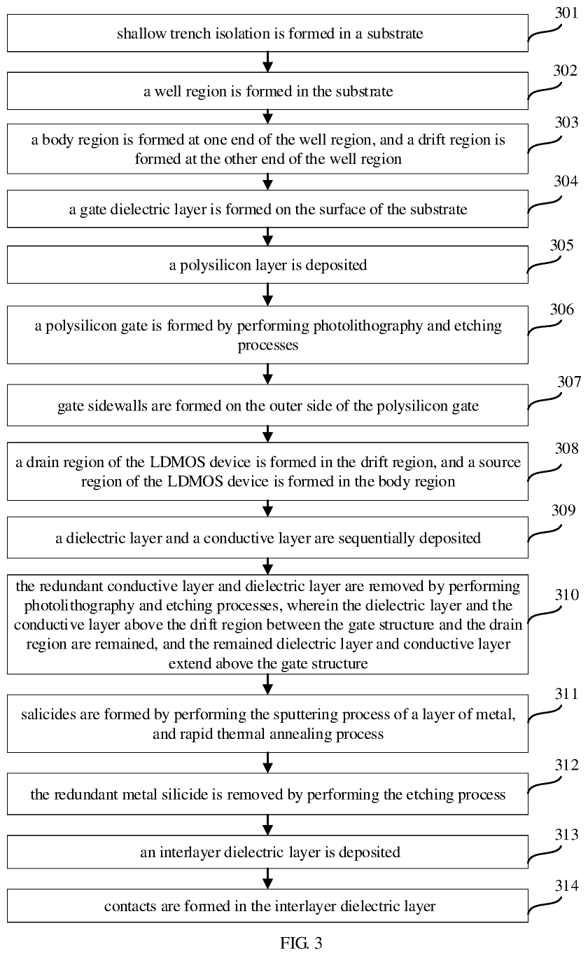

FIG. 3 is a flowchart of a method for manufacturing an LDMOS device, according to another embodiment of the present application.

In step 301, shallow trench isolation is formed in a substrate.

The shallow trench isolation defines active device regions for LDMOS devices and/or CMOS devices.

In step 302, a well region is formed in the substrate.

In step 303, a body region is formed at one end of the well region, and a drift region is formed at the other end of the well region.

In step 304, a gate dielectric layer is formed on the surface of the substrate.

In some examples, the gate dielectric layer is an oxide layer.

In step 305, a polysilicon layer is deposited.

The polysilicon layer is deposited on the gate dielectric layer.

In step 306, a polysilicon gate is formed by performing photolithography and etching processes.

Performing a photolithography process to define the polysilicon gate region, and performing an etching process to the polysilicon layer to form the polysilicon gate of the LDMOS device. The polysilicon gate of the LDMOS device covers a portion of the drift region and a portion of the body region by crossing from one to the other.

In some examples, after the polysilicon gate is formed, lightly doped drain implantation of the source region and the drain region is performed on the outside of the polysilicon gate.

In step 307, gate sidewalls are formed on the outer side of the polysilicon gate.

In some examples, the material of the gate sidewall consists an oxide layer and a silicon nitride layer. The oxide layer is formed on the outer side of the polysilicon gate, the silicon nitride layer is deposited, and then the silicon nitride layer is etched back until the polysilicon layer is exposed, to form the gate sidewalls of the LDMOS device.

In step 308, a drain region of the LDMOS device is formed in the drift region, and a source region of the LDMOS device is formed in the body region.

During the ion implantation process, the drain region of the LDMOS device in the drift region and form the source region of the LDMOS device in the body region are formed. In the manufacturing process, there would be a plurality of photolithography processes and ion implantation processes. After the ion implantation process, perform the annealing process.

In step 309, a dielectric layer and a conductive layer are sequentially deposited.

The dielectric layer is deposited on the substrate, and the dielectric layer is non-conductive.

In some examples, the dielectric layer is an oxide layer.

The conductive layer is deposited on the dielectric layer.

In some examples, the conductive layer is a metal layer.

In some examples, the conductive layer is a polysilicon layer. In an example, the polysilicon layer in the salicide block layer is a doped polysilicon layer.

In step 310, the redundant conductive layer and dielectric layer are removed by performing photolithography and etching processes, wherein the dielectric layer and the conductive layer above the drift region between the gate structure and the drain region are remained, and the remained dielectric layer and conductive layer extend above the gate structure.

Since the salicide block layer is used to prevent formation of salicide on the surface of the drift region between the gate structure and the drain region, the salicide block layer above the drift region between the gate structure and the drain region needs to be remained, and the salicide block layer in other regions needs to be removed.

A region where the metal silicide barrier layer that needs to be remained is defined by performing a photolithography process, and then the redundant conductive layer and dielectric layer are removed sequentially via etching processes. The remained salicide block layer covers the dielectric layer and the conductive layer above the drift region between the gate structure and the drain region, and the remained salicide block layer extends above the gate structure, referring to FIG. 1.

The salicide block layer is formed by stacking the dielectric layer and the conductive layer. In addition to the function of preventing the formation of the salicides, the salicide block layer can also be used as a field plate to improve the breakdown voltage and reliability of the LDMOS device.

In step 311, salicides are formed by performing the sputtering process of a layer of metal, and rapid thermal annealing process.

A layer of metal such as Ti, Co, or Ni is formed on the substrate via the sputtering process; and then, the rapid thermal annealing is performed such that the metal layer reacts with the polysilicon below the metal layer to form the metal silicide.

If the conductive layer in the salicide block layer is a metal layer, the metal sputtered on the conductive layer during the formation of the salicides and the metal layer in the salicide block layer together form the conductive layer.

If the conductive layer in the salicide block layer is a polysilicon layer, the salicides are also formed on the polysilicon layer in the salicide block layer.

In step 312, the redundant metal silicide is removed by performing the etching process.

In some examples, the redundant salicide is removed by performing a wet etching process, and the salicide on the top of the drain region, the top of the source region, and the top of the gate structure are remained.

It should be noted that if the conductive layer in the salicide block layer is a polysilicon layer, the salicides on the conductive layer are also remained.

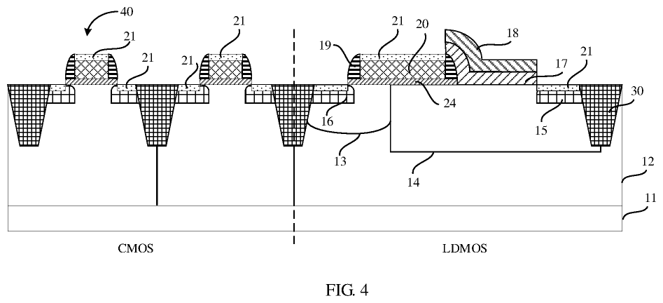

In one example, referring to FIG. 4, a CMOS device and an LDMOS device are both made on the substrate 11. A gate structure 40 of the CMOS device includes a polysilicon gate and gate sidewalls. When the salicides 21 are formed in an LDMOS device region, the salicides 21 are also formed on the top of the polysilicon gate of the CMOS device, the top of a source region, and the top of a drain region of the CMOS device.

In step 313, an interlayer dielectric layer is deposited.

In step 314, contacts are formed in the interlayer dielectric layer.

The contacts correspond to the drain region, the source region, the gate structure, and the salicide block layer. The drain region, the source region, the gate structure, and the salicide block layer are respectively led out from the contacts.

The contacts are formed in the interlayer dielectric layer by performing a photolithography process and an etching process.

It should be noted that the method for manufacturing an LDMOS device according to one embodiment of the present application can be used to manufacture P-type LDMOS devices as well as N-type LDMOS devices. If the LDMOS device is an N-type device, the well region is P-type, the drift region is N-type, the body region is P-type, and doping types of the source region and the drain region are N-type; and if the LDMOS device is a P-type device, the well region is N-type, the drift region is P-type, the body region is N-type, and doping types of the source region and the drain region are P-type.

Obviously, the foregoing embodiments are merely for clear description of made examples, and are not limitations on the implementations. For those of ordinary skill in the art, other different forms of changes or modifications can be made on the basis of the above description. There is no need and cannot be exhaustive for all implementations. And, the obvious changes or modifications introduced thereby are still within the protection scope of this application.

What is claimed is:

1. An LDMOS device, comprising: a substrate, a well region in the substrate, a body region, a drift region, a gate structure, and a salicide block layer, wherein
the body region and the drift region are in the well region, a drain region is at one end of the drift region, and a source region is at one end of the body region;
the gate structure covers a portion of the drift region and a portion of the body region by crossing from one to the other, and a gate dielectric layer is between the gate structure and the substrate;
the salicide block layer is composed of stacked dielectric layer and conductive layer;
the salicide block layer covers the drift region between the gate structure and the drain region, and the salicide block layer extends above the gate structure;
salicides are separately disposed on the tops of the drain region, the source region, and the gate structure; and
the drain region, the source region, the gate structure, and the salicide block layer are respectively led out from contacts in an interlayer dielectric layer.

2. The LDMOS device, according to claim 1, wherein the gate structure comprises a polysilicon gate and gate sidewalls; and
the salicide is disposed on the top of the polysilicon gate.

3. The LDMOS device, according to claim 1, wherein the conductive layer in the salicide block layer is a metal layer.

4. The LDMOS device, according to claim 1, wherein the conductive layer in the salicide block layer consists a polysilicon layer and a salicide layer on the polysilicon layer.

5. A method for manufacturing an LDMOS device, comprising:
forming shallow trench isolation in a substrate, wherein the shallow trench isolation defines active device regions;
forming a well region in the substrate;
forming a body region at one end of the well region, and forming a drift region at the other end of the well region;
forming a gate dielectric layer on the surface of the substrate;
forming a gate structure of the LDMOS device, wherein the gate structure covers a portion of the drift region and a portion of the body region by crossing from one to the other;
forming a drain region of the LDMOS device in the drift region, and forming a source region of the LDMOS device in the body region;
forming a salicide block layer, wherein the salicide block layer is composed of stacked dielectric layer and conductive layer, the salicide block layer covers the drift region between the gate structure and the drain region, and the salicide block layer extends above the gate structure;
forming salicides on the tops of the drain region, the source region, and the gate structure;
depositing an interlayer dielectric layer; and
forming contacts in the interlayer dielectric layer, wherein the contacts correspond to the drain region, the source region, the gate structure, and the salicide block layer.

6. The method for manufacturing an LDMOS device, according to claim 5, wherein the forming a salicide block layer comprises:
sequentially depositing a dielectric layer and a conductive layer; and
removing the redundant conductive layer and dielectric layer by performing photolithography and etching processes, wherein the dielectric layer and the conductive layer above the drift region between the gate structure and the drain region are remained, and the remained dielectric layer and conductive layer extend above the gate structure.

7. The method for manufacturing an LDMOS device, according to claim 5, wherein the conductive layer is a metal layer.

8. The method for manufacturing an LDMOS device, according to claim 5, wherein the conductive layer is a polysilicon layer.

9. The method for manufacturing an LDMOS device, according to claim 5, wherein the forming a gate structure of the LDMOS device on the surface of the substrate comprises:
depositing a polysilicon layer;
forming a polysilicon gate by performing photolithography and etching processes, wherein the gate structure covers a portion of the drift region and a portion of the body region by crossing from one to the other; and
forming gate sidewalls on the sides of the polysilicon gate.

10. The method for manufacturing an LDMOS device, according to claim 5, wherein the forming salicides on the tops of the drain region, the source region, and the gate structure comprises:
forming a layer of metal on the substrate by sputtering process, and performing rapid thermal annealing to form the salicide; and
removing the redundant salicide by performing an etching process, wherein the salicides on the tops of the drain region, the source region and the gate structure are remained.

11. The method for manufacturing an LDMOS device, according to claim 10, wherein if the conductive layer in the salicide block layer is a polysilicon layer, the salicide on the conductive layer is remained.
